(19) United States
(12) Patent Application Publication
(10) Pub. No.: US 2013/0256728 A1
(43) Pub. Date: Oct. 3, 2013

(54) LIGHT EMITTING DEVICE PACKAGE

(71) Applicant: SAMSUNG ELECTRONICS CO., LTD., Suwon-si (KR)

(72) Inventor: Jong Wook PARK, Hwaseong (KR)

(73) Assignee: SAMSUNG ELECTRONICS CO., LTD., Suwon-si (KR)

(21) Appl. No.: 13/835,362

(22) Filed: Mar. 15, 2013

(30) Foreign Application Priority Data
Mar. 28, 2012 (KR) 10-2012-0031765

(51) Int. Cl. H01L 33/60

(52) U.S. Cl. CPC H01L 33/60
USPC 257/98

(57) ABSTRACT

A light emitting device package includes a light emitting device which emits light, and an encapsulating part provided on a path of the light emitted from the light emitting device and formed by mixing a transparent resin with metallic particles which reflect and scatter at least a portion of the light emitted from the light emitting device.

### CROSS-REFERENCE TO RELATED APPLICATION

This application claims priority from Korean Patent Application No. 10-2012-0031765 filed on Mar. 28, 2012, in the Korean Intellectual Property Office, the disclosure of which is incorporated herein by reference in its entirety.

### BACKGROUND

1. Field

Apparatuses consistent with exemplary embodiments relate to a light emitting device package.

2. Description of Related Art

A semiconductor light emitting device is a semiconductor device able to emit light of various colors due to electron-hole recombination occurring at a p-n junction between p-type and n-type semiconductors when current is applied thereto. Such a semiconductor light emitting device is advantageous over a filament-based light emitting device in that it has a long lifespan, low power consumption, superior initial-operating characteristics, high vibration resistance, and the like. These factors have continually boosted the demand for semiconductor light emitting devices. In recent years, the applications of semiconductor light emitting devices have been extended to display devices, automobile headlights, general lighting apparatuses and the like, and accordingly, various optical characteristics thereof are in demand.

Light emitted from semiconductor light emitting devices may move in a linear manner while having a low amount of diffusion. For this reason, semiconductor light emitting devices may not be suitable for interior lighting apparatuses required to irradiate a wide area. Accordingly, semiconductor light emitting devices have been developed and used in small-sized lamps such as portable lanterns and the like, but they may be problematic for use in interior lighting apparatuses in many households.

### SUMMARY

One or more exemplary embodiments may provide a light emitting device package emitting light having superior diffusivity and high luminance.

According to an aspect of an exemplary embodiment, there is provided a light emitting device package including: a light emitting device which emits light; and an encapsulating part provided on a path of the light emitted from the light emitting device and formed by mixing a transparent resin with metallic particles which reflect and scatter at least a portion of the light emitted from the light emitting device.

The metallic particles may include silver (Ag) or a metal having an amount of reflectivity equal to or greater than a reflectivity of silver (Ag).

The metallic particles may be in the form of a powder.

The metallic particles may be formed by coating metallic powder grains with an insulating film.

The metallic particles may have a particle diameter of 1 μm to 5 μm.

The metallic particles may have a concentration of 1 wt % to 5 wt % with respect to the transparent resin.

The transparent resin may be selected from the group consisting of polymethyl methacrylate (PMMA), polystyrene, polyurethane, benzoguanamine resin, epoxy resin and silicon resin.

The encapsulating part may further include phosphor particles which wavelength-convert the light emitted from the light emitting device and emit the wavelength-converted light.

The metallic particles and the phosphor particles may be uniformly dispersed within the encapsulating part.

The light emitting device package may further include first and second lead frames electrically connected to the light emitting device and spaced apart from each other.

The light emitting device and the first and second lead frames may be connected by wire bonding or flip-chip bonding.

According to an aspect of another exemplary embodiment, there is provided a light emitting device package including: a light emitting device which emits light; first and second lead frames electrically connected to the light emitting device; a package body having a cavity which is opened to expose the light emitting device and the first and second lead frames; and an encapsulating part provided within the cavity, encapsulating the light emitting device, and formed by mixing a transparent resin with metallic particles which reflect and scatter at least a portion of the light emitted from the light emitting device.

The metallic particles may include silver (Ag) or a metal having an amount of reflectivity equal to or greater than a reflectivity of silver (Ag).

The metallic particles may be in the form of a powder.

The metallic particles may be formed by coating metallic powder grains with an insulating film.

The metallic particles may have a particle diameter of 1 μm to 5 μm.

The metallic particles may have a concentration of 1 wt % to 5 wt % with respect to the transparent resin.

The transparent resin may be selected from the group consisting of polymethyl methacrylate (PMMA), polystyrene, polyurethane, benzoguanamine resin, epoxy resin and silicon resin.

The encapsulating part may further include phosphor particles which wavelength-convert the light emitted from the light emitting device and emit the wavelength-converted light.

The metallic particles and the phosphor particles may be uniformly dispersed within the encapsulating part.

The light emitting device and the first and second lead frames may be connected by wire bonding or flip-chip bonding.

According to an aspect of another exemplary embodiment, there is provided a light emitting apparatus including: a semiconductor light emitting device which emits light; and a transparent material through which the emitted light passes, wherein the transparent material includes particles mixed within the transparent material, the particles being configured to diffuse the light.

### BRIEF DESCRIPTION OF THE DRAWINGS

The above and/or other aspects, features, and advantages will be more clearly understood from the following detailed description of exemplary embodiments taken in conjunction with the accompanying drawings, in which:

FIG. 1 is a cross-sectional view of a light emitting device package according to an exemplary embodiment;

FIG. 2 is a cross-sectional view of a light emitting device package according to another exemplary embodiment;

FIG. 3 is a cross-sectional view of a light emitting device package according to yet another exemplary embodiment;

FIG. 4 is a cross-sectional view of a light emitting device package according to still another exemplary embodiment; and

FIG. 5 is a cross-sectional view of a light emitting device package according to yet another exemplary embodiment.

### DETAILED DESCRIPTION

Exemplary embodiments will now be described in detail with reference to the accompanying drawings.

The inventive concept may, however, be embodied in many different forms and should not be construed as being limited to the exemplary embodiments set forth herein. Rather, these embodiments are provided so that this disclosure will be thorough and complete, and will fully convey the scope of the inventive concept to those skilled in the art.

In the drawings, the shapes and dimensions of elements may be exaggerated for clarity, and the same reference numerals will be used throughout to designate the same or like elements.

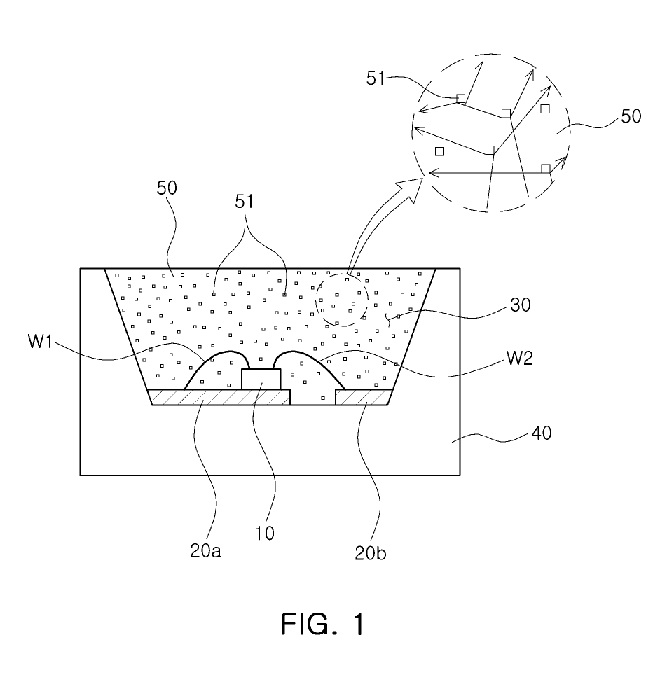

FIG. 1 is a cross-sectional view of a light emitting device package according to an exemplary embodiment. A light emitting device package according to the present exemplary embodiment includes a light emitting device 10, first and second lead frames 20a and 20b electrically connected to the light emitting device 10, a package body 40 having a cavity 30 opened to expose the light emitting device 10 and the first and second lead frames 20a and 20b, and an encapsulating part 50 provided within the cavity 30 and encapsulating the light emitting device 10.

In the present exemplary embodiment, as shown in FIG. 1, one of the first and second lead frames 20a and 20b may include a mounting area for the light emitting device 10. In addition, the light emitting device 10 in the present embodiment is electrically connected to the first and second lead frames 20a and 20b using first and second bonding wires W1 and W2. However, the light emitting device 10 may be directly electrically connected to the lead frame 20a, providing the mounting area, and may only be connected to the other frame 20b by a bonding wire. Alternatively, without the bonding wires, the light emitting device 10 may be configured using a flip-chip bonding method.

The light emitting device 10 may utilize a light emitting device emitting red, blue, green or ultraviolet light, but is not limited to being a light emitting device emitting light having a particular wavelength. More specifically, the light emitting device 10 may be formed of nitride semiconductor layers including n-type and p-type semiconductor layers. The n-type and p-type semiconductor layers may have a compositional formula of AlₓIn_{y}Ga_{(1-x-y)}N (0=x=1, 0=y=1, and 0=x+y=1). For example, GaN, AlGaN, InGaN or the like may be used. In addition, Si, Ge, Se, Te or the like may be used as n-type impurities and Mg, Zn, Be or the like may be used as p-type impurities.

An active layer formed between the n-type and p-type semiconductor layers emits light having a predetermined level of energy through electron-hole recombination. The active layer may have a multi-quantum well (MQW) structure in which quantum well layers and quantum barrier layers are alternately stacked. For example, a GaN/InGaN structure may be used.

Meanwhile, the n-type and p-type semiconductor layers and the active layer may be formed of semiconductor materials other than nitride semiconductors, for example, materials having a compositional formula of AlₓIn_{y}Ga_{(1-x-y})P (0=x=1, 0=y=1, and 0=x+y=1).

A light emitting device formed of such semiconductor materials may be suitable for emitting red light.

The first and second lead frames 20a and 20b may be spaced apart from each other to be electrically separated. The first and second lead frames 20a and 20b may be formed of metals having superior electrical and thermal conductivity, such as gold (Au), silver (Ag), copper (Cu) or the like.

The package body 40 may be formed of a resin that is opaque and/or has high reflectivity. The package body 40 may be formed of a polymer resin easily subjected to injection molding. However, the material for the package body 40 is not limited thereto. The package body 40 may be formed of various other resin materials or non-conductive materials such as ceramics or the like.

The encapsulating part 50 may be formed within the cavity 30 formed in the upper portion of the package body 40 to cover the light emitting device 10 such that the light emitting device 10 may be protected thereby. The encapsulating part 50 may be formed of a mixture of a transparent resin and metallic particles 51.

In the case in which the encapsulating part 50 is formed by mixing the transparent resin with the metallic particles 51, light generated from the light emitting device 10 may be reflected by colliding with the metallic particles 51 to be scattered before being emitted outwardly as shown in the enlarged view of FIG. 1.

That is, the light generated from the light emitting device 10 may be scattered due to diffused reflection through colliding with the metallic particles 51 included in the encapsulating part 50. Therefore, the light generated from the light emitting device 10 may be extensively diffused, rather than being focused on the upper portion of the light emitting device 10. In addition, since the light generated from the light emitting device 10 may be reflected by the metallic particles 51 to be scattered, an amount of light emitted outwardly from the light emitting device package may be increased to thereby improve light extraction efficiency. Furthermore, heat generated in the light emitting device 10 may be transferred to the package body 40 or emitted outwardly through the metallic particles 51 having high thermal conductivity, such that the heat may be effectively released therefrom. As a result, reliability of the light emitting device package including a lifespan thereof or the like may be improved.

The metallic particles 51 may include silver (Ag) or a metal having an amount of reflectivity equal to or greater than that of silver (Ag) in order that the light generated from the light emitting device 10 may collide with the metallic particles 51 to be easily reflected and scattered thereby. It is understood that the particles are not limited to being metallic particles, and may alternatively include other types of particles capable of reflecting and diffusing light.

Here, the transparent resin may be any material so long as the material allows the light generated from the light emitting device 10 to be transmitted and have the metallic particles 51 stably dispersed therein. In particular, any one of polymethyl methacrylate (PMMA), polystyrene, polyurethane, benzoguanamine resin, epoxy resin and silicon resin may be used therefor. It is understood that materials other than a transparent resin may be used.

The encapsulating part 50 may be formed by mixing the transparent resin with a curing agent and the metallic particles 51. The metallic particles 51 may be a powder included within the encapsulating part 50. An amount of the metallic particles 51 may be variously adjusted according to a desired level of luminance.

In addition, the metallic particles 51 may have an average particle diameter of 1 μm to 5 μm. Here, the average particle diameter refers to an average particle diameter of individual metallic particles or a representative particle diameter thereof. When the metallic particles 51 are excessively small, it is difficult for the surfaces of the metallic particles 51 to reflect the light generated from the light emitting device 10 with high reflectivity. In the case that the metallic particles 51 are excessively large, there is a difference in thermal expansion between the transparent resin and the metallic particles 51 of the encapsulating part 50 due to the heat generated in the light emitting device 10, and cracks may occur within the encapsulating part 50.

The concentration of the metallic particles 51 with respect to the transparent resin may range from approximately 1 wt % to 5 wt %. In a case in which the concentration of the metallic particles 51 is less than 1 wt %, light scattering effects caused by diffused reflection may be insignificant. In a case in which the concentration of the metallic particles 51 exceeds 5 wt %, light scattering effects may be high, but light loss due to light scattering and reflection may be increased to thereby deteriorate light emission efficiency.

In addition, the metallic particles 51 may be formed by coating metallic powder grains with an insulating film. In a case in which the metallic powder grains are coated with the insulating film, the metallic particles 51 may be prevented from migrating toward the bonding wire or the lead frames formed of metallic materials within the light emitting device package.

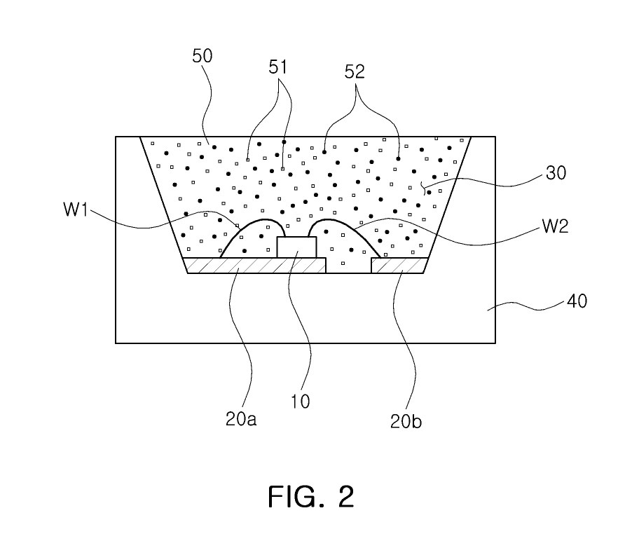

FIG. 2 is a cross-sectional view of a light emitting device package according to another exemplary embodiment.

According to this exemplary embodiment, the encapsulating part 50, which includes the metallic particles 51, further includes phosphor particles 52 excited by light emitted from the light emitting device 10 and which emit light which is wavelength-converted by the phosphor particles 52. Specifically, the phosphor particles 52 may convert incident light into light having one of yellow, red and green wavelengths, and types of the phosphors 52 may be determined based on the wavelength of light desired to be emitted from the light emitting device 10. For example, in a case in which phosphor particles, which convert incident light into light having a yellow wavelength, are used in conjunction with a semiconductor light emitting device emitting blue light, a semiconductor light emitting device which emits white light may be obtained.

The phosphor particles 52 may have a particle diameter of 1 μm to 30 μm, and the metallic particles 51 may have a particle diameter of 1 μm to 5 μm. In a case in which the diameters of the phosphor particles 52 and the metallic particles 51 are similar to each other, the phosphor particles 52 and the metallic particles 51 may be uniformly dispersed within the encapsulating part 50. In a case in which metallic particles 51 have a particle diameter similar to that of the phosphor particles 52, uniformity in terms of the dispersion of the metallic particles and the phosphor particles may be effectively achieved.

In this manner, in a case in which the metallic particles 51 and the phosphor particles 52 are uniformly distributed in the encapsulating part 50, the light generated from the light emitting device 10 may be reflected by the metallic particles 51 to be scattered and the phosphor particles 52 may be irradiated with the scattered light. Since more phosphor particles are irradiated with a relatively large amount of light, wavelength conversion efficiency may be increased.

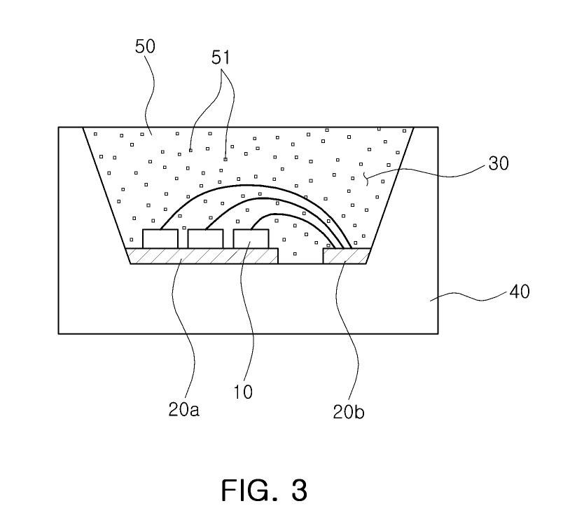

FIG. 3 is a cross-sectional view of a light emitting device package according to yet another exemplary embodiment.

With reference to FIG. 3, the light emitting device 10 includes a plurality of light emitting devices 10 emitting light having different wavelengths. Specifically, the light emitting devices 10 may include blue, green and red light emitting devices. However, the light emitting devices 10 are not limited thereto, and types, number and other characteristics thereof may be variously modified.

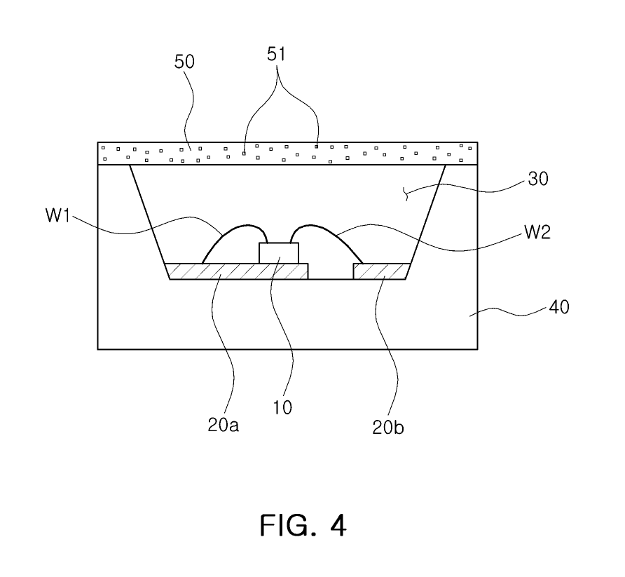

FIG. 4 is a cross-sectional view of a light emitting device package according to still another exemplary embodiment.

As shown in FIG. 4, the encapsulating part 50 including the metallic particles 51 is disposed on a light emitting surface spaced apart from the light emitting device 10 by a predetermined distance. It is understood that the predetermined distance is not limited to any particular distance and may be many different distances according to various criteria.

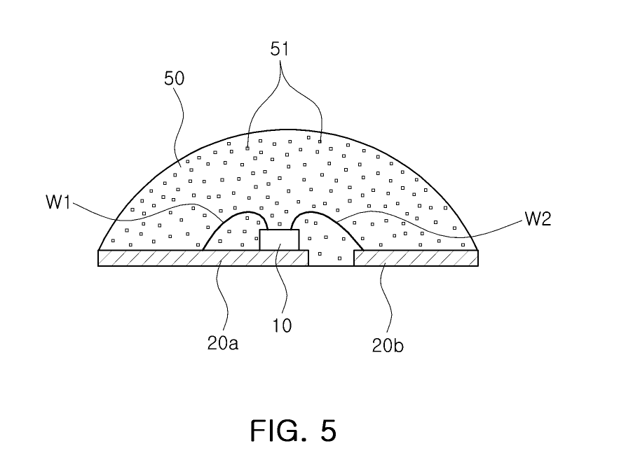

FIG. 5 is a cross-sectional view of a light emitting device package according to yet another exemplary embodiment.

With reference to FIG. 5, the light emitting device 10 is mounted on the first and second lead frames 20a and 20b which are electrically connected thereto. The first and second lead frames 20a and 20b may be respectively connected to terminals of the light emitting device 10 having different polarities to be electrically separated from each other. The electrical connection of the light emitting device 10 may be implemented by wire bonding, flip-chip bonding, or the like.

Here, the encapsulating part 50 may be shaped to include a semispherical surface, a convex or concave curved surface or the like, and may have various other shapes as well. In addition, the encapsulating part 50 may be applied to the light emitting device 10 to be in contact therewith. Since the encapsulating part 50 surrounds the light emitting device 10, the encapsulating part 50 may protect the light emitting device 10 and serve as a lens which determines light distribution according to the shape thereof.

As set forth above, a light emitting device package according to exemplary embodiments can emit light having superior diffusivity and high luminance.

A light emitting device package according to exemplary embodiments may achieve several advantages as compared to the related art, including an increased reliability due to enhanced light uniformity and effective thermal emissions.

While the present disclosure has been shown and described in connection with the exemplary embodiments, it will be apparent to those skilled in the art that modifications and variations can be made without departing from the spirit and scope of the exemplary embodiments as defined by the appended claims.

What is claimed is:

1. A light emitting device package comprising:
a light emitting device which emits light; and
an encapsulating part provided on a path of the light emitted from the light emitting device and formed by mixing a transparent resin with metallic particles which reflect and scatter at least a portion of the light emitted from the light emitting device.

2. The light emitting device package of claim 1, wherein the metallic particles include silver (Ag) or a metal having an amount of reflectivity equal to or greater than a reflectively of silver (Ag).

3. The light emitting device package of claim 1, wherein the metallic particles are in the form of a powder.

4. The light emitting device package of claim 1, wherein the metallic particles are formed by coating metallic powder grains with an insulating film.

5. The light emitting device package of claim 1, wherein the metallic particles have a particle diameter of 1 μm to 5 μm.

6. The light emitting device package of claim 1, wherein the metallic particles have a concentration of 1 wt % to 5 wt % with respect to the transparent resin.

7. The light emitting device package of claim 1, wherein the transparent resin is selected from the group consisting of polymethyl methacrylate (PMMA), polystyrene, polyurethane, benzoguanamine resin, epoxy resin and silicon resin.

8. The light emitting device package of claim 1, wherein the encapsulating part further includes phosphor particles which wavelength-convert the light emitted from the light emitting device and emit the wavelength-converted light.

9. The light emitting device package of claim 8, wherein the metallic particles and the phosphor particles are uniformly dispersed within the encapsulating part.

10. A light emitting device package comprising:
a light emitting device which emits light;
first and second lead frames electrically connected to the light emitting device;
a package body having a cavity which is opened to expose the light emitting device and the first and second lead frames; and
an encapsulating part provided within the cavity, encapsulating the light emitting device, and formed by mixing a transparent resin with metallic particles which reflect and scatter at least a portion of the light emitted from the light emitting device.

11. The light emitting device package of claim 10, wherein the metallic particles include silver (Ag) or a metal having an amount of reflectivity equal to or greater than a reflectivity of silver (Ag).

12. The light emitting device package of claim 10, wherein the metallic particles are in the form of a powder.

13. The light emitting device package of claim 10, wherein the metallic particles are formed by coating metallic powder grains with an insulating film.

14. The light emitting device package of claim 10, wherein the metallic particles have a particle diameter of 1 μm to 5 μm.

15. The light emitting device package of claim 10, wherein the metallic particles have a concentration of 1 wt % to 5 wt % with respect to the transparent resin.

16. The light emitting device package of claim 1, further comprising first and second lead frames electrically connected to the light emitting device and spaced apart from each other.

17. The light emitting device package of claim 16, wherein the light emitting device and the first and second lead frames are connected by wire bonding or flip-chip bonding.

18. A light emitting apparatus, comprising:
a semiconductor light emitting device which emits light; and
a transparent material through which the emitted light passes,
wherein the transparent material comprises particles mixed within the transparent material, the particles being configured to diffuse the light.

19. The light emitting apparatus of claim 18, wherein the transparent material comprises a transparent resin.

20. The light emitting apparatus of claim 18, wherein the particles comprise metallic particles.
